(19) United States
(12) Patent Application Publication
(10) Pub. No.: US 2026/0072056 A1
(43) Pub. Date: Mar. 12, 2026

(54) SYSTEMS AND METHODS FOR INTERPOSER SEATING INDICATION

(71) Applicant: Advanced Micro Devices, Inc., Santa Clara, CA (US)

(72) Inventors: Ravi B. Bingi, Austin, TX (US); Mahesh Prabhu, Bangalore (IN)

(73) Assignee: Advanced Micro Devices, Inc., Santa Clara, CA (US)

(21) Appl. No.: 18/828,993

(22) Filed: Sep. 9, 2024

(51) Int. Cl. G01R 1/04; G01R 19/25; G01R 31/28; H05K 1/11; H05K 1/18

(52) U.S. Cl. CPC G01R 1/0466; G01R 19/2503; G01R 31/2896; H05K 1/11; H05K 1/181; H05K 2201/10325

(57) ABSTRACT

A method can include receiving, in a socket, a semiconductor device package, wherein the socket includes two or more second electrical contacts positioned to connect two or more first electrical contacts of the semiconductor device package to a second voltage source. The method can also include connecting, by two or more resistors, the two or more first electrical contacts of the semiconductor device package to a first voltage source. The method can additionally include indicating, by a logic circuit, a status of a first connection of the two or more first electrical contacts to the second voltage source based on a voltage of a second connection of the two or more resistors to the first voltage source. Various other methods and systems are also disclosed.

### BACKGROUND

An integrated circuit package includes a block of semiconductor material encapsulated in a supporting case that prevents physical damage and corrosion. The case, known as a package, supports the electrical contacts which connect the device to a printed circuit board. Some integrated circuits can connect to the printed circuit board by pads that can be implemented as contacts of a land grid array (LGA).

The LGA is a type of surface-mount packaging for integrated circuits (ICs) that provides a grid of contacts (e.g., pads or lands) on the underside of a package. An LGA package can be electrically connected to a printed circuit board (PCB) either by the use of a socket or by soldering directly to the board. The LGA package is notable for having pins on a socket (i.e., when a socket is used) rather than an integrated circuit.

Sockets can accept semiconductor device packages, such as processor packages, and can be actuated to apply a force that holds pins and/or pads of the socket (e.g., interposer) and package (e.g., processor(s)) in contact with one another. Achieving proper seating of a package in a socket can accomplish suitable electrical contact between a socket and package, thus allowing the package to operate properly within the socket. Seating actuators, such as heat sinks and/or socket force frame mechanisms, can vary for different socket designs, and some actuators can permit adjustment of force applied in different socket regions and/or positioning of a package within the socket. Once set, these actuators can maintain proper seating of a package, thus maintaining proper electrical contact between a socket and a package.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an example system for interposer seating indication.

FIG. 2 is a flow diagram of an example method for interposer seating indication.

FIG. 3 is an isometric view of an example socket on a printed circuit board.

FIG. 4 is a schematic view of an example device for interposer seating indication.

FIG. 5 is a diagrammatic view of example circuitry for interposer seating indication.

FIG. 6 is a graphical illustration of an example data structure for interposer seating indication.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

Physical dimensions of the processor packages are increasing with the increased demand for integration of cores, IO devices and their associated power requirements. A typical socketed server processor now has upwards of 7000+ pins/pads. Ensuring that these pins make solid contact with the socket pins is beneficial. Further, High Volume Manufacturing (HVM) and Defective Parts Per Million (DPPM) quality metrics require proper identification and debugging of processor attachment issues on motherboards.

The traditional approach has been to provide one presence pin to a processor to detect processor seating in the socket. This detection assumes that if the single presence pin is contacting a socket pin, the rest of the processor package is coplanar and contacting the socket as well. While this technique can prove successful on smaller processor packages, detection based on a single presence pin is limiting due to variances in coplanarity associated with large packages, motherboards, and/or socket force frame mechanisms. The disclosed systems and methods can alleviate this issue and allow for extended coverage to ensure proper processor and socket contact.

The present disclosure is generally directed to interposer seating indication. For example, by configuring two or more resistors to connect two or more first electrical contacts of a semiconductor device package to a first voltage source and configuring a logic circuit to indicate a status of a first connection of the two or more first electrical contacts to a second voltage source based on a voltage of a second connection of the two or more resistors to the first voltage source, the disclosed systems and methods can achieve numerous benefits.

The disclosed systems and methods can achieve a variety of benefits arising in the context of large processor packages. For example, the disclosed systems and methods can detect whether the processor or interposer housed in a socket is properly contacting socket pins, the benefits of which can be applicable to larger sockets with finer pin pitch. Additionally, a logic circuit on a motherboard can detect any potential attachment issues with heatsink actuated versus force frame actuated sockets at scale. Such a circuit can be configured to report to a board management controller (BMC) which segment of pins are having contact issues and this data can be used for updating field replaceable units (FRUs) and for at scale debugging. These capabilities can improve HVM system assembly quality improvement, socket and package attachment quality, and at scale debugging capabilities.

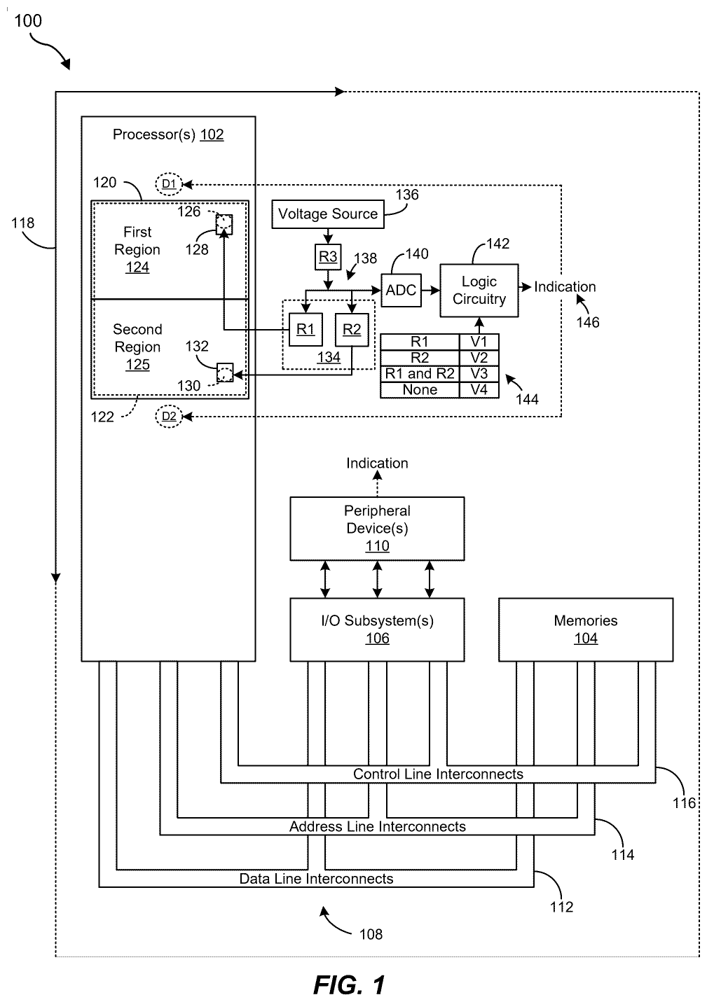

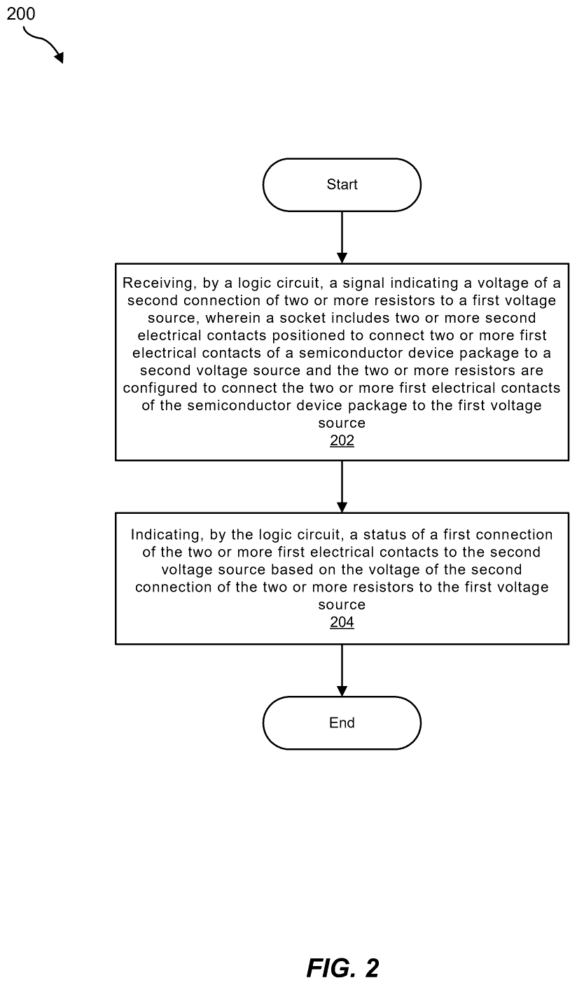

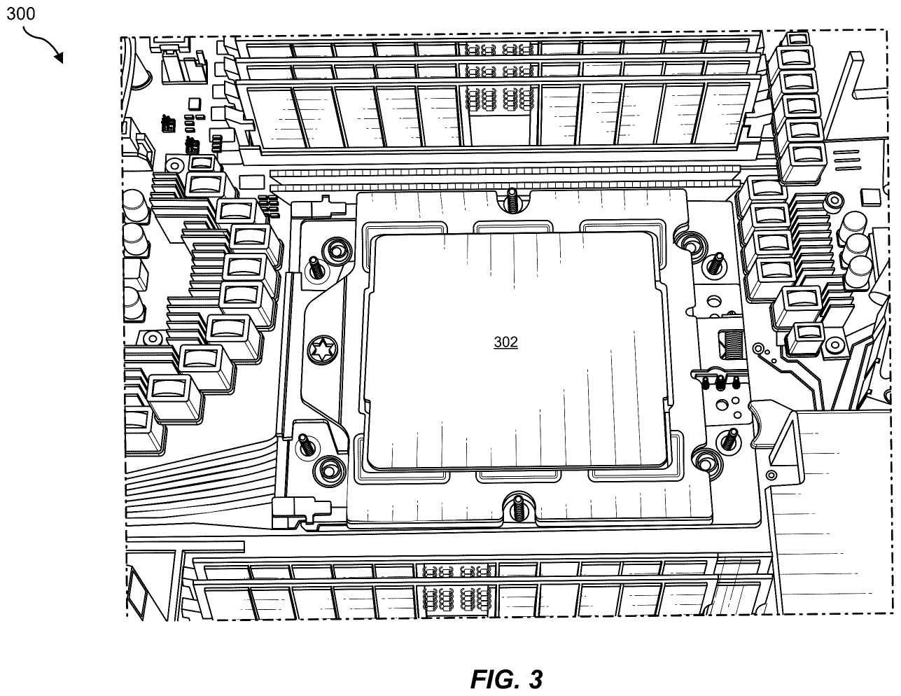

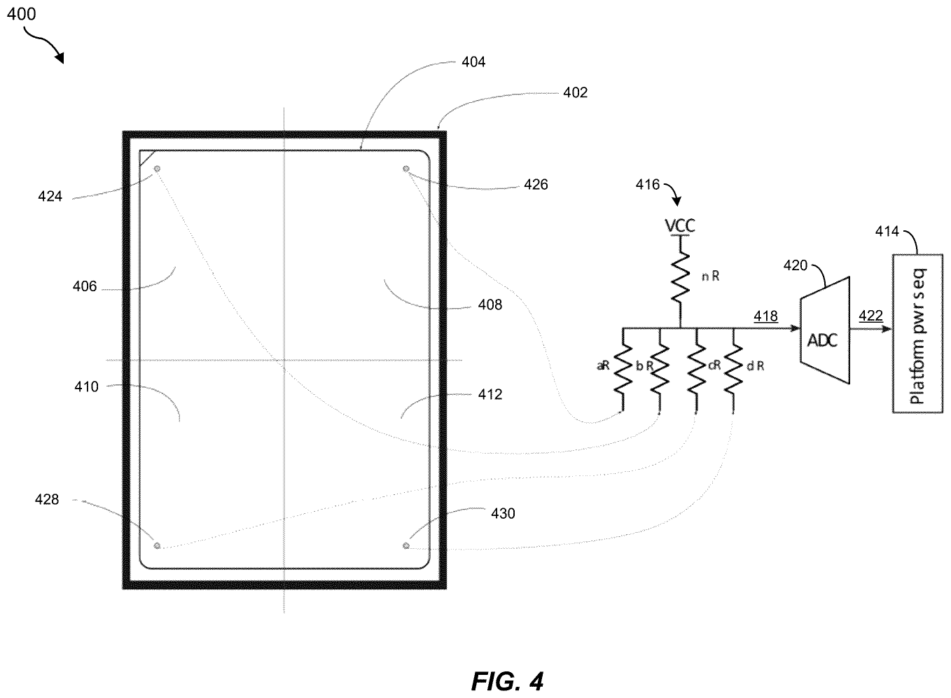

The following will provide, with reference to FIG. 1, detailed descriptions of example systems for interposer seating indication. Detailed descriptions of corresponding methods will also be provided in connection with FIG. 2. In addition, detailed descriptions of example sockets will be provided in connection with FIG. 3. Further, detailed descriptions of example devices, circuitry, and data structures for interposer seating indication will be provided in connection with FIGS. 4-6.

In one example, a device can include two or more resistors that are configured to connect two or more first electrical contacts of a semiconductor device package to a first voltage source and a logic circuit that is configured to indicate a status of a first connection of the two or more first electrical contacts to a second voltage source based on a voltage of a second connection of the two or more resistors to the first voltage source.

Another example can be the previously described example device further including an analog to digital converter that generates a signal based on the voltage of the second connection.

Another example can be any of the previously described example devices, wherein the logic circuit corresponds to at least one of a platform controller or a power sequencer.

Another example can be any of the previously described example devices, further including a socket that is configured to receive the semiconductor device package and that includes two or more second electrical contacts positioned to connect the two or more first electrical contacts of the semiconductor device package to the second voltage source.

Another example can be any of the previously described example devices, wherein the two or more second electrical contacts are located in different regions of the socket.

Another example can be any of the previously described example devices, wherein the logic circuit specifically indicates different regions of the socket in which the two or more first electrical contacts of the semiconductor device package are not connected to the second voltage source.

Another example can be any of the previously described example devices, wherein the logic circuit specifically indicates the different regions based on a data structure that records unique voltages for the two or more resistors and one or more combinations thereof.

Another example can be any of the previously described example devices, wherein the two or more second electrical contacts include four contacts located in in four different quadrants of the socket.

Another example can be any of the previously described example devices, wherein the two or more first electrical contacts and the two or more second electrical contacts correspond to at least one of pins or pads of a land grid array.

Another example can be any of the previously described example devices, wherein resistance values of the two or more resistors are different from one another.

In one example, a system can include a semiconductor device package including two or more presence pins and a printed circuit board including a socket that includes two or more pins positioned to connect the two or more presence pins to a second voltage source when the semiconductor device package is seated in the socket, a resistor array that is configured to connect the two or more presence pins to a first voltage source, and a logic circuit that is configured to indicate a status of a first connection of the two or more presence pins to the second voltage source based on a voltage of a second connection of the resistor array to the first voltage source.

Another example can be the previously described example system, further including an analog to digital converter that generates a signal based on the voltage of the second connection.

Another example can be any of the previously described example systems, wherein the logic circuit corresponds to at least one of a platform controller or a power sequencer.

Another example can be any of the previously described example systems, wherein the two or more pins include four pins located in different quadrants of the socket, the two or more presence pins include four presence pins located in different quadrants of the semiconductor device package, and the resistor array includes four resistors having different resistance values.

Another example can be any of the previously described example systems, wherein the logic circuit specifically indicates the different quadrants of the socket and the semiconductor device package in which the two or more presence pins of the semiconductor device package are not connected to the second voltage source.

Another example can be any of the previously described example systems, wherein the logic circuit specifically indicates the different quadrants of the socket and the semiconductor device package based on a lookup table that records unique voltages for the four resistors and combinations thereof.

In one example, a method can include receiving, by a logic circuit, a signal indicating a voltage of a second connection of two or more resistors to a first voltage source, wherein a socket includes two or more second electrical contacts positioned to connect two or more first electrical contacts of a semiconductor device package to a second voltage source and the two or more resistors are configured to connect the two or more first electrical contacts of the semiconductor device package to the first voltage source, and indicating, by the logic circuit, a status of a first connection of the two or more first electrical contacts to the second voltage source based on the voltage of the second connection of the two or more resistors to the first voltage source.

Another example can be the previously described example method, further including generating, by an analog to digital converter, the signal based on the voltage of the second connection.

Another example can be any of the previously described example methods, wherein the two or more second electrical contacts are located in different regions of the socket.

Another example can be any of the previously described example methods, further including specifically indicating, by the logic circuit, different regions of the socket in which the two or more first electrical contacts of the semiconductor device package are not connected to the second voltage source.

FIG. 1 illustrates an example system 100 for interposer seating indication. For example, system 100 can include one or more processors 102, one or more memories 104, and one or more input/output (I/O) subsystems 106 connected by a system bus 108. Processors 102 can include central processing units (CPUs) and/or co-processors, such as graphics processing units (GPUs), accelerator processing units (APUs), arithmetic logic units (ALUs), etc. Memories 104 can correspond to electronic holding places for the instructions and/or data that a computer needs to reach quickly, such as cache memory, main memory, and/or secondary memory. I/O subsystems 106 can correspond to devices that transfer data to and/or from a computer and control communication between processors 102 and peripheral devices 110. Peripheral devices 110 can correspond to devices that connect to a core computing unit, such as monitors, mice, keyboards, printers, external memory, etc. In turn, I/O subsystems 106 can include controllers for each of the peripheral devices 110. One or more processors 102, one or more memories 104, and one or more input/output (I/O) subsystems 106 can be implemented as one or more semiconductor device packages connected to one or more printed circuit boards. Some or all of processors 102, memories 104, I/O subsystems 106, system bus 108, and/or peripheral devices 110 can be implemented on a printed circuit board 118, such as a motherboard.

As shown in FIG. 1, a system bus 108 can be a communication system that transfers data between components inside a computer, or between computers. System bus 108 can include various interconnects, such as data line interconnects 112, address line interconnects 114, and control line interconnects 116. Data line interconnects 112, in the context of technology and computing, can refer to a communication path that facilitates the transmission of data between devices or systems. Address line interconnects 114 can refer to a physical connection between a CPU/chipset and memory and specify which address to access in the memory. Control line interconnects 116 can receive signals that manage varied chip operations (e.g., scan and write). One or more processors 102 can perform interposer seating indication as described herein.

As shown in FIG. 1, processors 102 can include a socket 120 receiving a semiconductor device package 122, such as a processor package, seated therein. Socket 120 and semiconductor device package 122 can include a first region 124 and a second region 125. Semiconductor device package 122 can include a first presence pin 126 in the first region 124 and socket 120 can include a first pin 128 (e.g., a ground pin) in the first region 124. First pin 128 can be positioned in first region 124 to connect first presence pin 126 to when semiconductor device package 122 is seated in socket 120. Semiconductor device package 122 can also include a second presence pin 130 in second region 125 and socket 120 can also include a second pin 132 (e.g., another ground pin) in the second region 125. Second pin 132 can be positioned in second region 125 to connect second presence pin 130 to a voltage source (e.g., ground) when semiconductor device package 122 is seated in socket 120.

Regions of a socket and/or semiconductor device package can include multiple pins and/or pads of the socket and/or semiconductor device package. For example, each region can include two or more pins and/or pads. Example regions of a socket and/or semiconductor device package can include halves, quadrants, or other even divisions of a surface of a socket and/or semiconductor device package. Regions of a socket and/or semiconductor device package can be symmetrical (e.g., quadrants, halves, etc.) or asymmetrical. Also, regions of a socket and/or semiconductor device package can be exclusive and/or can include subregions. For example, quadrants of the socket and/or semiconductor device package can correspond to four exclusive regions with respect to one another, pairs of which can correspond to subregions of halves of the socket and/or semiconductor device package. Regions of the socket and/or semiconductor device package can also be referred to as segments herein. In some implementations, a surface of a socket and/or semiconductor device package can include distal corners or areas of intersection of outer boundaries of the surface of the socket and/or semiconductor device package and, in some such implementations, each region may include one or more such corners or intersections.

As shown in FIG. 1, a resistor array 134 can connect first presence pin 126 and second presence pin 130 to a first voltage source 136 (e.g., VCC, an analog power supply, etc.). For example, resistor array 134 can include a first resistor R1 and a second resistor R2 connected in parallel to first voltage source 136. Resistor R1 can connect to first presence pin 126 and resistor R2 can connect to second presence pin 130. Connection (e.g., a first connection) of the presence pins 126 and 130 to a second voltage source (e.g., ground) can affect a voltage observed on a second connection 138 of resistor array 134 to first voltage source 136. A third resistor R3 can be connected between the first voltage source 136 and the second connection 138. An analog to digital converter 140 (ADC) can generate a signal (e.g., digital signal) based on the voltage of the second connection 138.

A voltage source can correspond to an electric circuit component that is used to create a potential difference between two points in an electric circuit. For example, and without limitation, a voltage source can correspond to an electrode, an anode, a cathode, a power supply, ground, etc. In this context, voltage sources can be power supplies that supply power at different voltage levels. In some implementations set forth herein, a first voltage source connected to presence pins by a resistor array can correspond to a power supply and a second voltage source connected to socket pins can correspond to ground. However, other implementations can employ a first voltage source connected to presence pins by a resistor array that corresponds to ground and a second voltage source connected to socket pins that corresponds to a power supply. In still other implementations, the first voltage source and the second voltage source can correspond to power supplies that supply power at different voltage levels.

As shown in FIG. 1, logic circuit 142 can receive the signal from ADC 140 and indicate a status of the first connection of presence pins 126 and 130 to the second voltage source (e.g., ground) based on the voltage of second connection 138 of resistor array 134 to first voltage source 136. For example, logic circuit 142 can corresponds to a platform controller and/or a power sequencer. In one example, logic circuit 142 can compare a voltage indicated by the signal received from ADC 140 to entries of a data structure 144 (e.g., a lookup table). In this context, resistors R1 and R2 can have different resistance values and data structure 144 can record unique voltages for resistors R1 and R2 individually, for a combination of resistors R1 and R2, and for a combination of neither resistor R1 nor resistor R2. In this way, logic circuit 142 can use a voltage indicated by the signal from ADC 140 to determine if only first pin 126 is connected to the second voltage source, if only second pin 130 is connected to the second voltage source, if both first pin 126 and second pin 130 are connected to the second voltage source, or if neither first pin 126 nor second pin 130 is connected to the second voltage source. Based on this determination, logic circuit 142 can provide an indication 146 of the connection status of first presence pin 126 and/or second presence pin 130. For example, the logic circuit 142 can specifically indicate the different regions 124 and 125 of the socket and the semiconductor device package in which the presence pins 126 and 130 of the package 122 are and/or are not connected to the second voltage source.

As shown in FIG. 1, logic circuit 142 can indicate the connection status of pins 126 and 130 in various ways. In one example, system 100 can include indicators D1 and D2 (e.g., diodes) respectively proximate to corresponding regions 124 and 125. Logic circuit 142 can activate and/or deactivate indicators D1 and/or D2 to indicate connection and/or disconnection in the different regions 124 and 125. In some implementations, indicators D1 and D2 can be in and/or on one or more seating actuators, such as heatsinks and/or force frames. In another example, indication 146 can be transmitted by system bus 108 to I/O subsystems 106 and thence to one or more peripheral devices 110 for display and/or audio notification. In another example, indication 146 can be written to one or more memories 104.

As shown in FIG. 1, system 100 includes two presence pins 126 and 130, two regions 124 and 125, two resistors R1 and R2 in a resistor array (e.g., a lower leg of a voltage divider circuit), and four data structure entries. However, other implementations of system 100 can include more than two regions, presence pins, and resistors and more than four data structure entries. For example and as described later herein, FIGS. 4-8 detail an implementation having four regions, presence pins, and resistors and sixteen data structure entries. More generally, system 100 and implementations thereof can include N regions, presence pins, and resistors and 2N data structure entries, where N is an integer greater than or equal to two.

FIG. 2 is a flow diagram of an example method 200 for interposer seating indication. As illustrated in FIG. 2, at step 202 one or more of the systems described herein can receive a signal. For example, logic circuit 142 can, as part of system 100 in FIG. 1, receive a signal indicating a voltage of a second connection of two or more resistors to a first voltage source, wherein a socket includes two or more second electrical contacts positioned to connect two or more first electrical contacts of a semiconductor device package to a second voltage source and the two or more resistors are configured to connect the two or more first electrical contacts of the semiconductor device package to the first voltage source.

The systems described herein can perform step 202 in a variety of ways. In one example, method 200 can, at step 202, position the two or more second electrical contacts (e.g., ground contacts) in different regions (e.g., halves, quadrants, etc.) of the socket. In some examples, method 200 can, at step 202, implement four contacts located in in four different quadrants (e.g., at outer corners) of the socket. In some implementations, method 200 can, at step 202, implement the second electrical contacts as pins and/or pads of a land grid array.

As shown in FIG. 2 at step 202, one or more of the systems described herein can connect the first electrical contacts to the first voltage source. For example, resistor array 134 can, as part of system 100 in FIG. 1, connect, by the two or more resistors, the two or more first electrical contacts of the semiconductor device package to the first voltage source.

The systems described herein can, at step 202, connect the first electrical contacts to the first voltage source in a variety of ways. In one example, method 200 can, at step 202, arrange the two or more resistors in a resistor array. In some implementations, method 200 can, at step 202, connect the first electrical contacts (e.g., presence pins) to a first voltage source (e.g., VCC, an analog power supply, etc.). In some examples, method 200 can, at step 202, connect a first resistor and a second resistor in parallel to the first voltage source. In some examples, method 200 can, at step 202, connect the first resistor to a first presence pin and the second resistor to a second presence pin. In some implementations, method 200 can, at step 202, employ two or more resistors that have resistance values that are different from one another.

As shown in FIG. 2 at step 204, one or more of the systems described herein can indicate a status. For example, logic circuit 142 can, as part of system 100 in FIG. 1, indicate a status of a first connection of the two or more first electrical contacts to the second voltage source based on the voltage of the second connection of the two or more resistors to the first voltage source.

The systems described herein can perform step 204 in a variety of ways. In one example, logic circuit 142 can, as part of system 100 in FIG. 1, specifically indicate different regions of the socket in which the two or more first electrical contacts of the semiconductor device package are not connected to the second voltage source. In some implementations, logic circuit 142 can, as part of system 100 in FIG. 1, specifically indicate the different regions based on a data structure that records unique voltages for the two or more resistors and one or more combinations thereof. In some examples, logic circuit 142 can, as part of system 100 in FIG. 1, activate and/or deactivate one or more indicators (e.g., diodes) respectively proximate to the different regions of the socket. In some of these implementations, logic circuit 142 can, as part of system 100 in FIG. 1, activate and/or deactivate these indicators based on connection and/or disconnection in the different regions of the socket. Additionally or alternatively, logic circuit 142 can, as part of system 100 in FIG. 1, transmit the status by a system bus to I/O subsystems and thence to one or more peripheral devices for display and/or audio notification. In still other examples, logic circuit 142 can, as part of system 100 in FIG. 1, write a connection status to one or more memories. In some examples, method 200 can, at step 204, implement the logic circuit in a platform controller and/or a power sequencer. In some implementations, ADC 140 can, as part of system 100 of FIG. 1, generate the signal based on the voltage of the second connection and output the signal to the logic circuit.

FIG. 3 illustrates an example socket 300 (e.g., a server socket) on a printed circuit board (e.g., a mother board). For example, socket 300 can receive therein a semiconductor device package 302. In some implementations, socket 300 can correspond to an LGA server socket and semiconductor device package 302 can correspond to a processor package and/or an LGA package. In some examples, socket 300 can include an interposer. A force frame and/or heat sink can be attached atop the socket and tightened down in order to seat the semiconductor device package 302 in the socket 300.

FIG. 4 illustrates an example device 400 for interposer seating indication. For example, device 400 can include a socket 402 (e.g., a server socket) having a semiconductor device package 404 (e.g., a processor package, an LGA package, etc.) seated therein. Socket 402 and package 404 can have four different regions 406, 408, 410, and 412 (e.g., four quadrants). Instead of using one presence pin, four presence pins, one in each region 406, 408, 410, and 412, can be identified based on mechanical modeling and mechanical test vehicle measurements and connected to a logic circuit 414 (e.g., a power sequencing component and/or a platform controller) on the motherboard. On the semiconductor device package these presence pins can be connected to a second voltage source (e.g., a digital ground (VSS)) by pins and/or pads 424, 426, 428, and 430 (e.g., of an interposer and/or socket) in regions 406, 408, 410, and 412.

As shown in FIG. 4, the presence pins can be routed through precision resistors aR, bR, cR, dR, and nR to a first voltage source 416 (e.g., VCC, an analog power supply, etc.) that is available in a standby state. The resultant voltage 418 can be connected to an ADC 420. ADC 420 can see different voltages depending on the number of presence pins contacting the socket 402. For example, based on a number of presence pins on the processor contacting the pins and/or pads 424, 426, 428, and 430, the voltage 418 can vary as follows:
where:

$$V = V CC \times {R}_{effective} / ( {R}_{effective} + nR ) ,$$

$${R}_{effective} = 1 / \{ ( 1 / aR ) + ( 1 / bR ) + ( 1 / cR ) + ( 1 / dR ) \} ,$$

and where V is the voltage, VCC is a source voltage from the first voltage source 416, and nR, aR, bR, cR, and dR are resistance values of the resistors nR, aR, bR, cR, and dR. Logic circuit 414 can receive an ADC output 422 providing a digital signal indicative of the voltage and use a data structure (e.g., a look-up table) to infer whether there is a good contact in all of the regions 406, 408, 410, and 412 and/or any regions 406, 408, 410, and 412 in which there is not good contact.

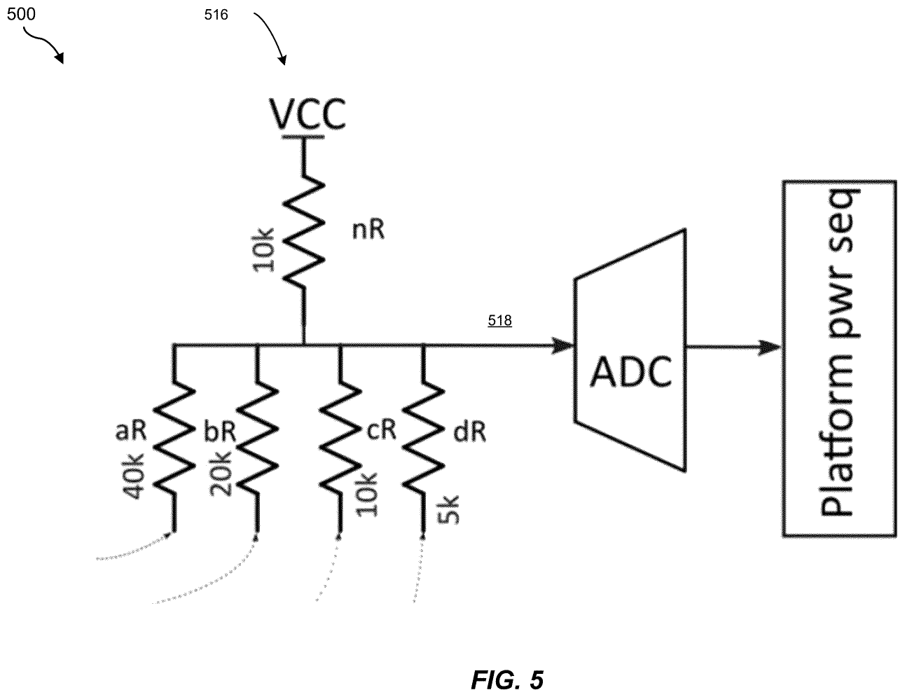

FIG. 5 illustrates an example circuit 500 for interposer seating indication. In theory, there is no minimum or maximum value limitation for resistors nR, aR, bR, cR, and dR used in this circuit 500. The resistors nR, aR, bR, cR, and dR form a voltage-divider circuit and only the ratio of the resistance values matter, not the absolute resistance values of resistors nR, aR, bR, cR, and dR. In practice, there can be a range of resistance values for resistors nR, aR, bR, cR, and dR which can provide a stable output voltage 518 while not drawing too much current from a first voltage source 516 (e.g., VCC, an analog power supply, etc.).

As shown in FIG. 5, an implementation that can provide a stable output voltage 518 while not drawing too much current from a first voltage source 516 can use different resistance values for some or all of the resistors nR, aR, bR, cR, and dR. For example, the resistors aR, bR, cR, and dR in a lower leg of the voltage divider can be selected in such a way that no two values are the same. In the example shown in FIG. 5, resistance values for resistors aR, bR, cR, and dR in the lower leg of the voltage divider (e.g., the resistor array) can correspond to forty kiloohms, twenty kiloohms, ten kiloohms, and 5 kiloohms, respectively. Thus, resistance values for resistors aR, bR, cR, and dR in the lower leg of the voltage divider can all be different from one another and result in different resistor value ratios for different combinations of connections of presence pins to the second voltage source (e.g., ground). A resistance value for resistor nR in the upper leg of the voltage divider does not have to be different from all of the resistance values for resistors aR, bR, cR, and dR. In the example shown in FIG. 5, the resistance value for resistor nR can correspond to ten kiloohms, which is the same as the resistance value for resistor cR in the resistor array. Alternatively, the resistance value for resistor nR can be different from all of the resistance values for resistors aR, bR, cR, and dR.

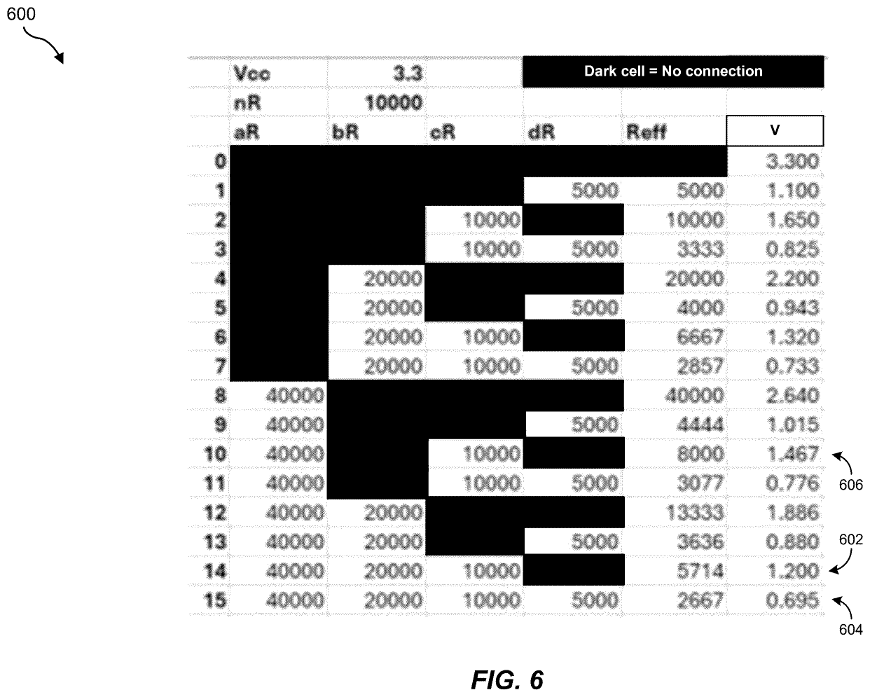

FIG. 6 illustrates an example data structure 600 for interposer seating indication. For example, the data structure 600 can be implemented as a lookup table of voltages for the different resistance values and different resistance value combinations. Using the resistance values chosen as detailed above with reference to FIG. 5, resistance values can be assigned to the resistors and a corresponding lookup-table of voltages can be created for the resistor values that are used. An expected voltage V can be unique for each of the sixteen combinations for the four presence pins. For example, if only a presence pin corresponding to dR is not making contact as shown in line 602, V can equal 1.200 V. However, if all pins make contact as in line 604, V can equal 0.695V.

The lookup table can be be calculated beforehand based on VCC and the values of resistors used and can be provided to a power sequencing component and/or platform controller. Based on this table, the power sequencing component and/or platform controller can determine which exact quadrants of the package are not contacting the socket. For example, if V=1.467 V, then the power sequencing component and/or platform controller can infer from line 606 that present pins in quadrants corresponding to those regions in which resistors bR and dR are connected are not contacting the socket.

As set forth above, the disclosed systems and methods can perform interposer seating indication. For example, by configuring two or more resistors to connect two or more first electrical contacts of a semiconductor device package to a first voltage source and configuring a logic circuit to indicate a status of a first connection of the two or more first electrical contacts to a second voltage source based on a voltage of a second connection of the two or more resistors to the first voltage source, the disclosed systems and methods can achieve numerous benefits.

The disclosed systems and methods can achieve a variety of benefits arising in the context of large processor packages. For example, the disclosed systems and methods can detect whether the processor or interposer housed in a socket is properly contacting socket pins, the benefits of which can be applicable to larger sockets with finer pin pitch. Additionally, a logic circuit on a motherboard can detect any potential attachment issues with heatsink actuated versus force frame actuated sockets at scale. Such a circuit can be configured to report to a board management controller (BMC) which segment of pins are having contact issues and this data can be used for updating field replaceable units (FRUs) and for at scale debugging. These capabilities can improve HVM system assembly quality improvement, socket and package attachment quality, and at scale debugging capabilities.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
two or more resistors that are configured to connect two or more first electrical contacts of a semiconductor device package to a first voltage source; and
a logic circuit that is configured to indicate a status of a first connection of the two or more first electrical contacts to a second voltage source based on a voltage of a second connection of the two or more resistors to the first voltage source.

2. The device of claim 1, further comprising:
an analog to digital converter that generates a signal based on the voltage of the second connection.

3. The device of claim 1, wherein the logic circuit corresponds to at least one of a platform controller or a power sequencer.

4. The device of claim 1, further comprising:
a socket that is configured to receive the semiconductor device package and that includes two or more second electrical contacts positioned to connect the two or more first electrical contacts of the semiconductor device package to the second voltage source.

5. The device of claim 4, wherein the two or more second electrical contacts are located in different regions of the socket.

6. The device of claim 5, wherein the logic circuit specifically indicates different regions of the socket in which the two or more first electrical contacts of the semiconductor device package are not connected to the second voltage source.

7. The device of claim 6, wherein the logic circuit specifically indicates the different regions based on a data structure that records unique voltages for the two or more resistors and one or more combinations thereof.

8. The device of claim 4, wherein the two or more second electrical contacts include four contacts located in in four different quadrants of the socket.

9. The device of claim 4, wherein the two or more first electrical contacts and the two or more second electrical contacts correspond to at least one of pins or pads of a land grid array.

10. The device of claim 1, wherein resistance values of the two or more resistors are different from one another.

11. A system, comprising:
a semiconductor device package including two or more presence pins; and
a printed circuit board including a socket that includes two or more pins positioned to connect the two or more presence pins to a second voltage source when the semiconductor device package is seated in the socket, a resistor array that is configured to connect the two or more presence pins to a first voltage source, and a logic circuit that is configured to indicate a status of a first connection of the two or more presence pins to the second voltage source based on a voltage of a second connection of the resistor array to the first voltage source.

12. The system of claim 11, further comprising:
an analog to digital converter that generates a signal based on the voltage of the second connection.

13. The system of claim 11, wherein the logic circuit corresponds to at least one of a platform controller or a power sequencer.

14. The system of claim 11, wherein the two or more pins include four pins located in different quadrants of the socket, the two or more presence pins include four presence pins located in different quadrants of the semiconductor device package, and the resistor array includes four resistors having different resistance values.

15. The system of claim 14, wherein the logic circuit specifically indicates the different quadrants of the socket and the semiconductor device package in which the two or more presence pins of the semiconductor device package are not connected to the second voltage source.

16. The system of claim 15, wherein the logic circuit specifically indicates the different quadrants of the socket and the semiconductor device package based on a lookup table that records unique voltages for the four resistors and combinations thereof.

17. A method comprising:
receiving, by a logic circuit, a signal indicating a voltage of a second connection of two or more resistors to a first voltage source, wherein a socket includes two or more second electrical contacts positioned to connect two or more first electrical contacts of a semiconductor device package to a second voltage source and the two or more resistors are configured to connect the two or more first electrical contacts of the semiconductor device package to the first voltage source; and
indicating, by the logic circuit, a status of a first connection of the two or more first electrical contacts to the second voltage source based on the voltage of the second connection of the two or more resistors to the first voltage source.

18. The method of claim 17, further comprising:
generating, by an analog to digital converter, the signal based on the voltage of the second connection.

19. The method of claim 17, wherein the two or more second electrical contacts are located in different regions of the socket.

20. The method of claim 17, further comprising:
specifically indicating, by the logic circuit, different regions of the socket in which the two or more first electrical contacts of the semiconductor device package are not connected to the second voltage source.
